(19) United States
(12) Patent Application Publication
(10) Pub. No.: US 2016/0133814 A1
(43) Pub. Date: May 12, 2016

(54) FUEL-FLEXIBLE THERMAL POWER GENERATOR FOR ELECTRIC LOADS

(71) Applicant: SHEETAK, INC., Austin, TX (US)

(72) Inventors: Uttam GHOSHAL, Austin, TX (US); Ayan GUHA, Austin, TX (US); Key KOLLE, Luling, TX (US); Himanshu POKHARNA, Saratoga, CA (US); Ravi PRASHER, Austin, TX (US); Ankita GHOSHAL, Austin, TX (US)

(73) Assignee: SHEETAK, INC., Austin, TX (US)

(21) Appl. No.: 14/391,967

(22) PCT Filed: Apr. 10, 2013
(86) PCT No.: PCT/US13/35986

§ 371 Date: Oct. 10, 2014

Related U.S. Application Data
(60) Provisional application No. 61/622,419, filed on Apr. 10, 2012.

(51) Int. Cl. H01L 35/32

(52) U.S. Cl. CPC H01L 35/32

(57) ABSTRACT

An apparatus and method configured to provide electric power from a thermal source. The apparatus may include a thermoelectric generator and a heat source. The apparatus may include a fuel source. The heat source may be combustive or non-combustive. The apparatus may also include a thermal battery. The heat source may be configured to combust a hydrocarbon fuel to generated heat. The apparatus may include one or more thermal diodes and/or a heat sink to remove waste heat. The method may include converting thermal energy into electrical energy using the apparatus. The method may also include powering a light or other electrical load using the apparatus. The present disclosure includes a method for manufacturing the apparatus.

### CROSS REFERENCE TO RELATED APPLICATIONS

This application claims the benefit of Provisional U.S. Patent Application No. 61/622,419 filed Apr. 10, 2012, which application is hereby incorporated by reference in its entirety.

### BACKGROUND OF THE DISCLOSURE

1. Field of the Disclosure

The present disclosure relates to an apparatus and method for generating electric power, and, in particular, powering an electric load using electricity generated from thermal energy by a thermoelectric generator.

2. Description of the Related Art

Access to reliable electric power is essential to education, social welfare and economic development. Nearly 1.6 billion people in the developing world live in rural areas without electricity and are isolated from the national power grids. Although renewable energy sources, such as light photovoltaic arrays and wind generators, are gaining traction for low-power (10 W) lighting needs, the utility of these alternatives is limited by high capital and installation costs and the intermittent nature of renewable energy power generation. For example, visible light photovoltaic arrays typically generate electricity for only 3-4 hours per day and are idle during the night and when the weather is cloudy or rainy. Visible light photovoltaic arrays also require augmentation with expensive battery storage technologies that are often not environmentally friendly. The large size of photovoltaic panels required for 50 W+ generation also limits portability.

The limited lighting and energy needs in households and businesses in rural areas and developing countries at large are addressed by costly, polluting, nonrenewable fuels such as kerosene and liquefied petroleum gas (LPG) in lamps and lanterns. For example, the efficiency of light generated per liter of kerosene consumed by a typical kerosene lantern is very poor (on the order of less than 10 kilo-lumen-hour/liter). These lamps also present health hazards due to incomplete combustion and production of toxic gases at high temperatures. What is needed is a low-cost, reliable, and highly efficient electric source that may use commonly available hydrocarbon fuels and is not restricted to connection to a power grid. The electricity may be generated to power lights and other electric devices while reducing the production of the undesirable gases on a lumens per unit of gas basis.

### BRIEF SUMMARY OF THE DISCLOSURE

In aspects, the present disclosure is related to an apparatus and method for generating electric power, and, in particular, powering an electric load using electricity generated from thermal energy by a thermoelectric generator. In some aspects, the present disclosure is related to generating light using a heat source and a thermoelectric generator.

One embodiment according to the present disclosure includes an apparatus for generating electric power, the apparatus comprising: a thermoelectric generator, the thermoelectric generator having a hot side and a cold side; a combustor manifold with a plurality of nozzles and in thermal communication with the hot side of the thermoelectric generator, wherein the combustor manifold has an input, and wherein areas of the plurality of nozzles are sized using a model based on a position of each nozzle relative to the input; and a fuel source connected to the input of the combustor manifold. Each of the plurality of nozzles may have a unique area, and the model may include a mathematical ratio. The mathematical ratio may be geometrical or exponential. The model may include the using the equation Aₙ=A₁βⁿ⁻¹, wherein Aₙ is the nth nozzle of the plurality of nozzles, A₁ is a nozzle of the plurality of nozzles that is located closest to the input, n is a nozzle position, and β is a geometrical ratio between adjacent nozzles of the plurality of nozzles. The apparatus may include a light absorbing layer disposed on the hot side of the thermoelectric generator and configured to convert light to heat; and a light director configured to transmit light to the light absorbing layer. The light director may include at least one of: i) a reflector and ii) a lens. The apparatus may also include a thermal battery in thermal communication with the combustor manifold and the hot side. The thermal battery may include an insulated housing and an energy storage material. The energy storage material may include phase change materials and/or exothermic hydration reaction materials. The apparatus may include an electric load such as an electric light and/or an electric battery-operated device. The thermoelectric generator may be a thin-film thermoelectric generator. The apparatus may include a heat sink and/or thermal diode to remove heat from the cold side.

Another embodiment according to the present disclosure includes a method of generating electric power, the method comprising: generating electric power using an apparatus, the apparatus comprising: a thermoelectric generator, the thermoelectric generator having a hot side and a cold side; a combustor manifold with a plurality of nozzles and in thermal communication with the hot side of the thermoelectric generator, wherein the combustor manifold has an input, and wherein areas of the plurality of nozzles are sized using a model based on a position of each nozzle relative to the input; and a fuel source connected to the input of the heat source. The step of generating electric power may comprise: generating heat with the combustor manifold; transmitting the heat to the hot side of the thermoelectric generator; and converting the heat to electricity using the thermoelectric generator. The method may further include storing the heat from the combustor manifold in a thermal battery; and conducting the heat from the thermal battery to the hot side of the thermoelectric generator. The method may include powering an electric load with the generated electricity. The method may include removing heat from the cold side of the thermoelectric generator, which may comprise drawing heat away from the cold side using a heat sink in thermal communication with the cold side with or without an thermal diode disposed between the heat sink and the cold side. The method may include shielding an electric load from heat at the heat sink, wherein the electric load is in electrical communication with the thermoelectric generator. If the apparatus includes a light absorbing layer disposed on the hot side and configured to convert light to heat, then the method may include directing light energy to the light absorbing layer.

Another embodiment according to the present disclosure includes an apparatus for generating electric power, the apparatus comprising: a thermoelectric generator, the thermoelectric generator having a hot side and a cold side; and a non-combustive heat source in thermal communication with the hot side. The non-combustive heat source is configured to transmit heat from at least one of: i) an exothermic chemical reaction, ii) a thermophysical phase change, iii) an optothermal phase change, and iv) radioactive decay.

Another embodiment according to the present disclosure includes a method of generating electric power, the method comprising: generating electric power using an apparatus, the apparatus comprising: a thermoelectric generator, the thermoelectric generator having a hot side and a cold side; a non-combustive heat source in thermal communication with the hot side of the thermoelectric generator. The method may include generating heat with the non-combustive heat source; transmitting the heat to the hot side of the thermoelectric generator; and converting the heat to electricity using the thermoelectric generator. The generating of heat may include at least one of: using heat from an exothermic chemical reaction; using heat from a thermophysical phase change; using heat from an optothermal phase change; and using heat from radioactive decay.

Another embodiment of the present disclosure may include a method of manufacturing an apparatus for generating electric power, the method comprising: disposing a combustor manifold with a plurality of nozzles in thermal communication with a hot side of a thermoelectric generator, wherein the combustor manifold has an input, and wherein areas of the plurality of nozzles are sized using a model based on a position of each nozzle relative to the input; and configuring a fuel source to deliver fuel to the combustor manifold. Each of the plurality of nozzles may have a unique area and wherein the model includes a mathematical ratio. The mathematical ratio may be one of: i) geometrical and ii) exponential. The model may use the equation Aₙ=A₁βⁿ⁻¹, wherein Aₙ is the nth nozzle of the plurality of nozzles, A₁ is a nozzle of the plurality of nozzles that is located closest to the input, n is a nozzle position, and β is a geometrical ratio between adjacent nozzles of the plurality of nozzles.

Another embodiment according to the present disclosure includes a method of manufacturing an apparatus for generating electric power, the method comprising: disposing a non-combustive heat source in thermal communication with a hot side of a thermoelectric generator, wherein the non-combustive heat source is configured to transmit heat from at least one of: i) an exothermic chemical reaction, ii) a thermophysical phase change, iii) an optothermal phase change, and iv) radioactive decay.

Examples of the more important features of the disclosure have been summarized rather broadly in order that the detailed description thereof that follows may be better understood and in order that the contributions they represent to the art may be appreciated. There are, of course, additional features of the disclosure that will be described hereinafter and which will form the subject of the claims appended hereto.

### BRIEF DESCRIPTION OF THE DRAWINGS

For a detailed understanding of the present disclosure, reference should be made to the following detailed description of the embodiments, taken in conjunction with the accompanying drawings, in which like elements have been given like numerals, wherein:

FIG. 1 a diagram of an electric power generation apparatus connected to electric loads according to one embodiment of the present disclosure;

FIG. 2 is a schematic of a thermal battery according to one embodiment of the present disclosure;

FIG. 3 is a schematic of a light generating apparatus according to one embodiment of the present disclosure;

FIG. 4 is a schematic of a light generating apparatus with a thermal diode according to another embodiment of the present disclosure;

FIG. 5 is a schematic of a light generating apparatus with a thermal barrier according to one embodiment of the present disclosure;

FIG. 6 is a schematic of a light generating apparatus of FIG. 1 with a cutaway of the thermal battery according to one embodiment of the present disclosure;

FIG. 7 is a schematic of a thermoelectric generator according to one embodiment of the present disclosure;

FIG. 8 is a schematic of a thermoelectric generator with a light absorbing layer according to one embodiment of the present disclosure;

FIG. 9 is a schematic of a thermoelectric generator with an atmospheric housing and a light absorbing layer according to one embodiment of the present disclosure;

FIG. 10 is a schematic of a combustor according to one embodiment of the present disclosure;

FIG. 11 is a flow chart for method of generating electric power using heat from a heat source with a thermoelectric generator according to one embodiment of the present disclosure;

FIG. 12 is a flow chart for a method of generating electric power using light from a light source with a thermoelectric generator according to one embodiment of the present disclosure; and

FIG. 13 is a flow chart for a method of manufacturing an electric power generation apparatus for electric loads according to one embodiment of the present disclosure.

### DETAILED DESCRIPTION OF THE DISCLOSURE

Generally, the present disclosure relates to an apparatus and method for generating electric power, and, in particular, powering an electric load using electricity generated from thermal energy by a thermoelectric generator. In some aspects, the present disclosure is related to generating light using a heat source and a thermoelectric generator. The present disclosure is susceptible to embodiments of different forms. They are shown in the drawings, and herein will be described in detail, specific embodiments of the present disclosure with the understanding that the present disclosure is to be considered an exemplification of the principles of the present disclosure and is not intended to limit the present disclosure to that illustrated and described herein.

The present disclosure is directed to power generation using a thermoelectric generator and a heat source. In some aspects, the present disclosure is directed to powering an electric load using heat generated by a heat source consuming a fuel. The fuel may be a hydrocarbon fuel, which may generate the heat through combustion. Suitable hydrocarbon fuels may include, but are not limited to, kerosene, liquefied petroleum gas (LPG), liquefied natural gas (LNG), raw natural gas (raw or refined), jet fuels, alcohols, and butane. In some embodiments, the heat source may generate heat through non-combustive chemical reaction.

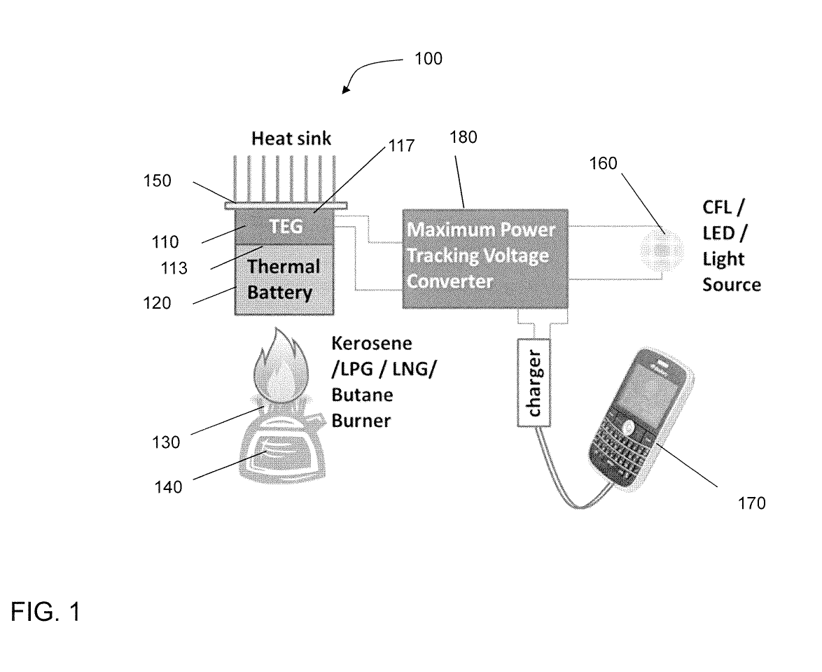

FIG. 1 shows a schematic of a power generating apparatus 100 according to one embodiment of the present disclosure. The apparatus 100 may include a thermoelectric generator 110. The thermoelectric generator 110 may include a hot side 113 and a cold side 117. The electric power output of the thermoelectric generator 110 may be dependent on a temperature difference between the hot side 113 and the cold side 117. A thermal battery 120 may be disposed in contact with the hot side 117. The thermal battery 120 may gradually release heat energy into the thermoelectric generator 110. The thermal battery 120 may store heat energy (become charged) from a heat source 130. The heat source 130 may generate heat by consuming fuel from a fuel source 140. The heat source 130 may be configured to generate heat through a suitable chemical reaction, such as combustion. In some embodiments, the heat source 130 may be identical to a thermal battery 120. The fuel source 140 may include, but is not limited to, one or more of: i) a fuel tank and ii) a fuel line. The fuel source 140 may include any combustible material, including, but not limited to, one or more of: i) kerosene, ii) liquefied petroleum gas, iii) liquefied natural gas, iv) butane, v) alcohol, and vi) biomass (wood, peat, etc.). Other heat generation sources may be based on one or more of: i) exothermic chemical reactions such as hydration of alkali and alkali metal salts (MgSO₄, MgCl₂, CaO), ii) thermophysical phase change, such as during magnetic ordering or grain ordering in shape memory alloys, iii) optothermal phase changes, and iv) nuclear (alpha- and beta-particle) decay reactions. Some of the heat from the hot side 113 may be transmitted to the cold side 117. A heat sink 150 may be in thermal communication with the cold side 117 to dissipate heat and reduce the temperature of the cold side 117. Drawing heat away from the cold side 117 aids in maintaining and/or maximizing a temperature differential across the thermoelectric generator 110. In some embodiments, the heat sink 150 and/or the thermal battery 120 may be optional. In some embodiments, the thermal battery 120 may be heated by the heat source 130 in a first location, and then the “charged” thermal battery 120 may be transported to and placed in thermal communication with the thermoelectric generator 110 at a second location for discharging and power generation.

The electrical power generated by the apparatus 100 may be transmitted to an electric load such as an electric light source 160 and/or an electric battery-operated device 170. The use of the light source 160 and the electric battery-operated device 170 as the electric load are exemplary and illustrative only, as any suitable electric load may used as would be understood by a person of ordinary skill in the art with the benefit of the present disclosure. In some embodiments, an optional voltage converter 180 may be disposed between the electric load 160, 170 and the apparatus 100 and configured to modify the output voltage of the thermoelectric generator 110 such that the voltage is suitable for the electric load 160, 170. In some embodiments, the voltage converter 180 may include a maximum power tracking circuit and/or a battery charger.

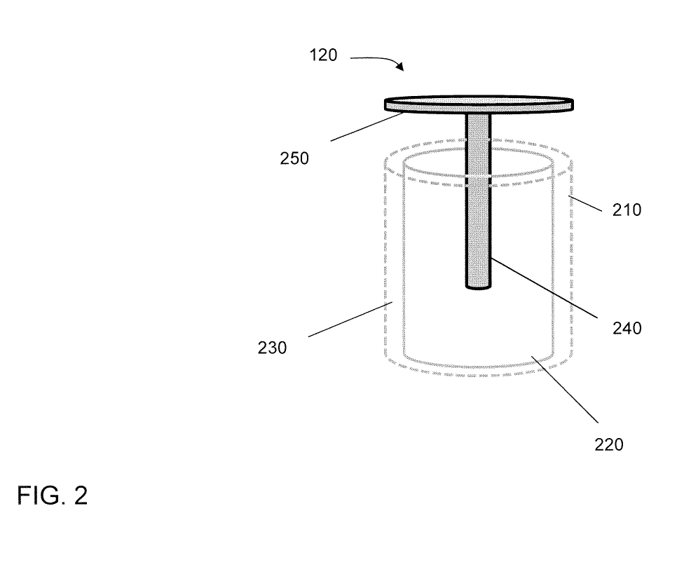

FIG. 2 shows a schematic of an exemplary thermal battery 120 according one embodiment of the present disclosure. The thermal battery 120 may include a housing 210 filled at least partly with an energy storage material 220. A heat insulation layer 230 may be disposed between the housing 210 and the energy storage material 220 to reduce heat leakage though the housing 210. The heat insulation layer 230 may include, but is not limited to, one or more of: i) a vacuum panel, ii) an aerogel, and iii) a high temperature ceramic fiber blankets. The housing 210 may have a heat conductor 240 in contact with the energy storage material 220. The heat conductor 240 may be configured to allow heat to flow out of the thermal battery 120 at a much greater rate than through the heat insulation layer 230. The heat conductor 240 may be attached to a heat plate 250. The heat plate 250 may be configured to distribute the heat over a greater surface area than the heat conductor 240. The heat plate 250 may be in physical contact with the hot side 113 of the thermoelectric generator 110. The heat plate 250 and the heat conductor 240 may be made of identical or different materials. In some embodiments, the heat plate 250 and the heat conductor 240 may be different sections of a single formed component.

The housing 210 may be made of a suitable material for containing the energy storage material 220, such as stainless steel. The housing 210 may be corrosion resistant and may be selected based on the type of energy storage material 220 used. The energy storage material 220 may be selected to release heat energy. The energy storage material 220 may also be selected for the ability to receive heat energy as well. One suitable energy storage material is a phase change material (PCM). PCMs may include materials with large latent heats of fusion and/or melting. PCMs may include molten salts, molten metals, molten metal alloys, ionic liquids, and metallic compounds with melting points within the safe operating range of the thermoelectric generator 110. The molten salts may include, but are not limited to, one or more of: sodium nitrate and potassium nitrate. The salts may store heat thermochemically or thermophysically depending on the temperature of operation. Generally, the molten salts are low cost materials that are nontoxic and non-flammable, and offer substantial saving over costly, toxic, and polluting electrochemical batteries. Some molten salts can store about 0.6 MJ/m3 and are widely used in light thermal plants. Suitable molten metals/metal alloys may include, but are not limited to, one or more of i) aluminum, ii) aluminum-silicon, iii) bismuth-tin, and iv) tin. The alloys may store heat thermophysically in a phase change. Suitable metal/metal alloys melt at temperatures below the maximum safe operating temperature of the thermoelectric generator 110. Suitable metallic compounds may include, but are not limited to, one or more of: i) Na₃AlF₆, ii) NaK₂AlF₆, and iii) Li₃AlF₆. These alloys have high thermal conductivity and latent heat of fusion which permits for a large storage of heat and efficient transfer of heat throughout the energy storage media (that is, a low Biot-number for the system). (Table I).

| | | | | Latent | |
|---|---|---|---|---|---|
| | Melting | | Solid Heat | Heat of | Thermal |
| | Point | Density | Capacity | Fusion | Conductivity |
| Material | (° C.) | (kg/m³) | (kJ/kg-k) | (kJ/kg) | (W/m-K) |
| NaNO₃ | 306 | 1.75 × 10³ | 1.5 × 10³ | 178 | 0.49 |
| Al | 660 | 2.36 × 10³ | 1.1 × 10³ | 321 | 220 |

Another suitable energy storage material is an alkali metal oxide or salt that exhibits an exothermic reaction in the presence of water. The energy storage material 220 may include substances selected for a reversible exothermic hydration reaction, such as alkali metal oxides like anhydrous MgO and CaO (lime) with water to form Mg(OH)₂ or Ca(OH)₂ or hydration of anhydrous MgSO₄ to form MgSO₄.7H₂O. When heat is added, a reverse reaction will occur to decompose hydroxides back to oxides or dehydrate MgSO₄.7H₂O back to anhydrous MgSO₄.

The heat conductor 240 and/or the heat plate 250 may be composed of a suitable material selected to provide a high thermal conductance path. An exemplary material that provides a high thermal conductance path is tungsten. Other refractory materials that provide high corrosion resistance and thermal conductance include, but not limited to, titanium, molybdenum, niobium, tantalum, and zirconium. One embodiment of the heat conductor 240 and/or the heat plate 250 may also be made of copper coated with nickel and a refractory metal such as tungsten. When the energy storage material 220, such as sodium nitrate, is heated to high temperatures (about 300 degrees Celsius and higher), the tungsten will not be degraded by the energy storage material 220. Another embodiment of the heat conductor 240 and/or the heat plate 250 may include one or more of: i) graphite, ii) composites of carbon nanotubes, iii) graphenes, iv) diamond-like carbon, and v) high temperature stable ceramics with high thermal conductance.

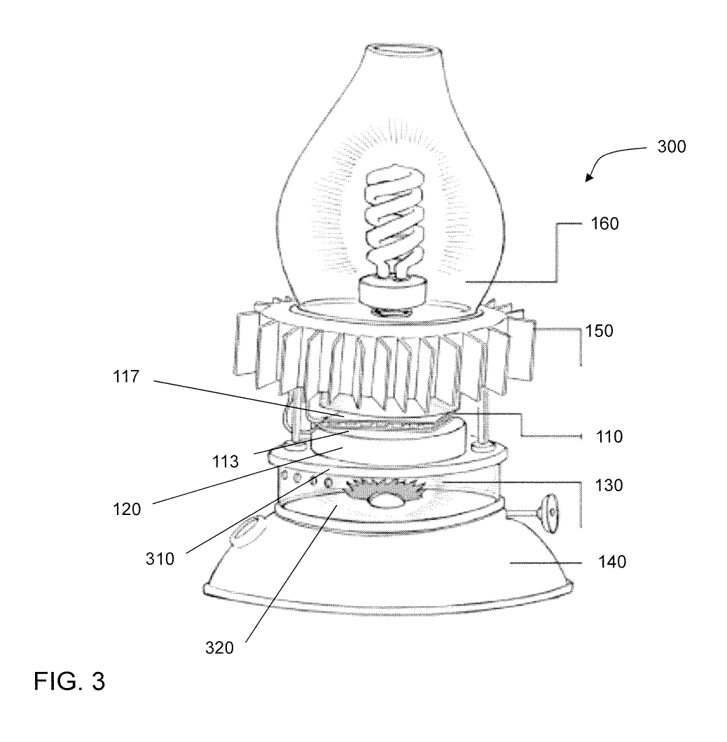

FIG. 3 shows an exemplary light generating apparatus 300 according to one embodiment of the present disclosure. The apparatus 300 may be configured to have dimensions that are suitable for transport and operation by a single person. The apparatus 300 may include a thermoelectric generator 110, a thermal battery 120, a heat source 130, and a fuel source 140. The hot side 113 of the thermoelectric generator 110 may be in thermal communication with the thermal battery 120 (if present) and/or the heat source 130. The cold side 117 of the thermoelectric generator 110 may be in thermal communication with a heat sink 150. In some embodiments, the heat sink 150 may have fins configured to increase the area of a heat dissipating surface of the heat sink 150, such as in a pin-fin or a plate-fin configuration. The apparatus 300 may also include an electric light source 160. The electric light source 160 may include, but is not limited to, one or more of: i) a compact fluorescent light, ii) a light emitting diode, iii) an incandescent bulb, (iv) halogen lamps and (v) a laser. In some embodiments, the heat sink 150 may be optional. In some embodiments, the heat sink 150 may be cooled by natural air convection. In some embodiments, the performance of the heat sink 150 may be enhanced by forced air cooling of the heat sink 150, such as from a fan (not shown).

Also shown is an optional heat plate 310 configured to distribute the heat of the heat source 130 along the surface of the thermal battery 120 that is in contact with the heat plate 310. In some embodiments, the heat plate 310 may be dimensioned so that the surface area of the heat plate 310 is approximately identical to the surface area of the hot side 113 of the thermoelectric generator 110. The heat source 130, in this case a combustor with a flame, may be shielded from air drafts and convection heat losses by a wind shield 320. The wind shield 320 may include sufficient access to the atmosphere for oxygen to reach the combustor, but may reduce excess air flow across the combustor to reduce heat loss and the chance of the flame being extinguished. The appearance of apparatus 300 as a hurricane lamp is exemplary and illustrative only, as other arrangements are envisioned as would be understood by a person of ordinary skill in the art with the benefit of the teachings of the present disclosure.

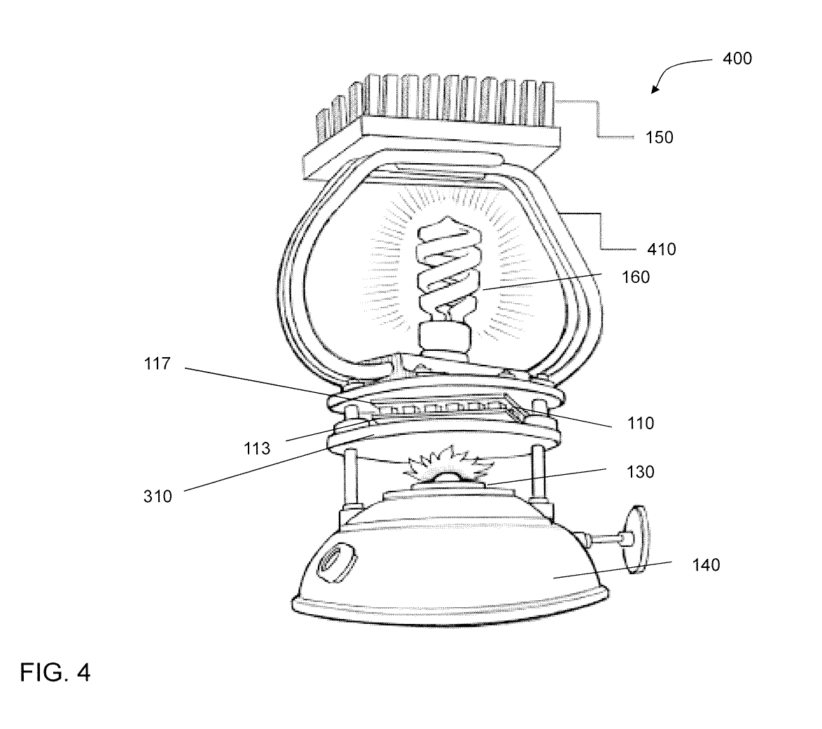

FIG. 4 shows another light generating apparatus 400 according to an embodiment of the present disclosure. Here, the heat sink 150 is in thermal communication with the cold side 117 by way of a thermal diode 410 disposed between the heat sink 150 and the cold side 117. The thermal diode 410 may include, but is not limited to, one or more of: i) a heat pipe and ii) a thermosyphon. The thermal diode 410 may be any device that has a thermal diodicity of more than one, that is, a device having a thermal conductance in one direction that is more than the thermal conductance in the reverse direction. The heat sink 150 is shown disposed above light source 160, however, this is exemplary and illustrative only, as the heat sink 150 may be disposed other arrangements that would be understood by a person of ordinary skill in the art with the benefit of the present disclosure. The use of the thermal diode 410 may allow the heat sink 150 to be disposed in position where the heat sink 150 is not in physical contact with the cold side 117 while maintaining performance of the heat sink 150. The thermal diode 410 may include a small evaporator chamber in thermal contact with the cold side 117 and one or more tubes coming out of the evaporator and terminating in the condenser at the heat sink 150. The tubes and the evaporator chamber at the bottom may be evacuated and filled with a condensable fluid. The fluid in the evaporator chamber closest to the cold side 117 may boil off as a vapor. The vapor may be transported to the top condenser (in thermal communication with the heat sink 150). When the heat sink 150 cools the vapor, the vapor condenses and trickles down into the evaporation chamber due to gravity and/or a wicking material present in the tubes. A common fluid for heat transfer that may be employed in the thermal diode 410 is water. Water may be used over a working range of about 25 degree Celsius to about 225 degrees Celsius. At higher temperatures, high temperature working fluids (for example NaK, Potassium, and Cesium) may be used in the thermal diode 410.

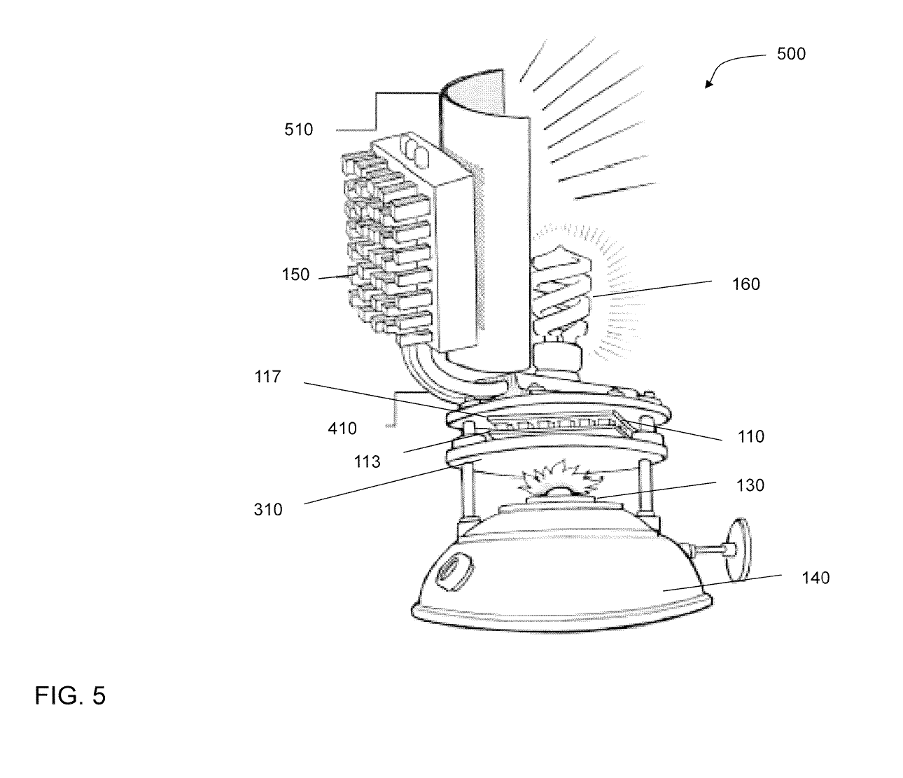

FIG. 5 shows another light generating apparatus 500 according to an embodiment of the present disclosure. Here, the heat sink 150 is shown disposed to the side of the electric light source 160. The heat sink 150 may be separated from the electric light source 160 by a thermal barrier 510. The thermal barrier 510 may be configured to reduce exposure of the electric light source 160 from the heat of the heat sink 150. In some embodiments, the thermal barrier 510 may also have the properties of a reflector, which may directionally enhance the light emitted by the electric light source 160.

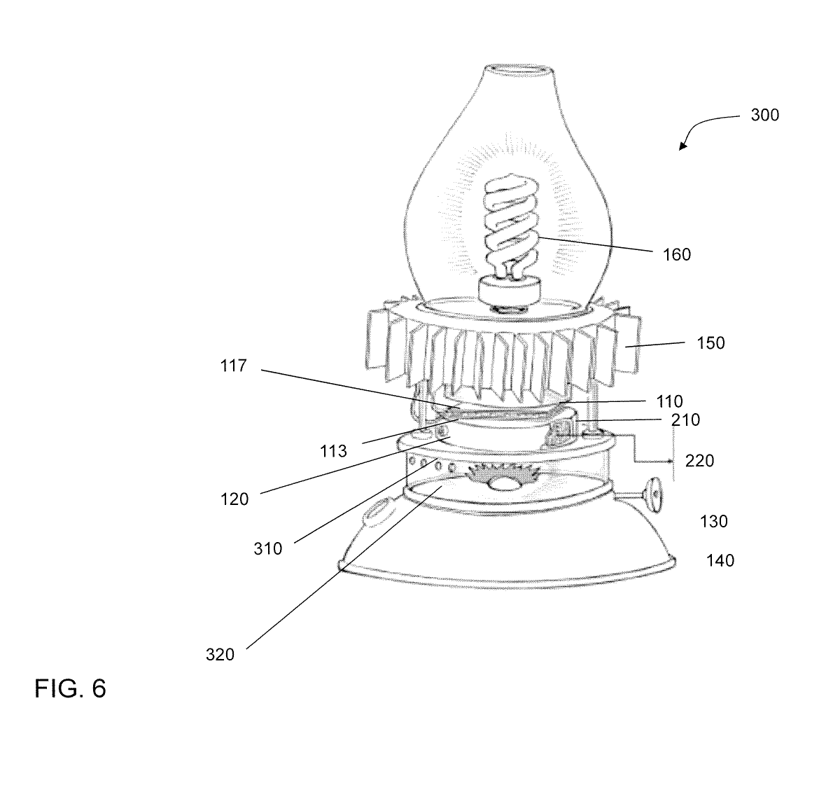

FIG. 6 shows the light generating apparatus 300 of FIG. 3 with a cutaway view of the thermal battery 120. Within the thermal battery 120 is shown the housing 210 and the energy storage material 220.

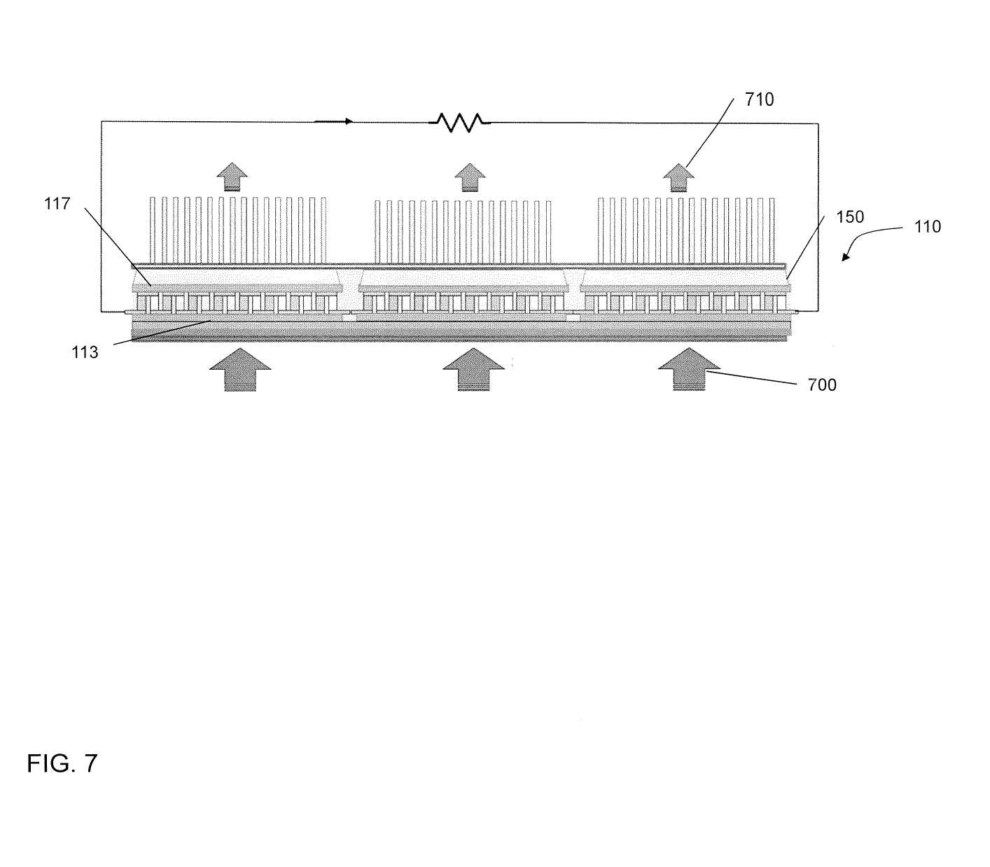

FIG. 7 shows an exemplary thermoelectric generator 110 according to one embodiment of the present disclosure. The cold side 117 is shown in contact with the heat sink 150, and heat energy 700 is shown entering the hot side 113. Excess heat energy 710 is shown being dissipated by the heat sink 150.

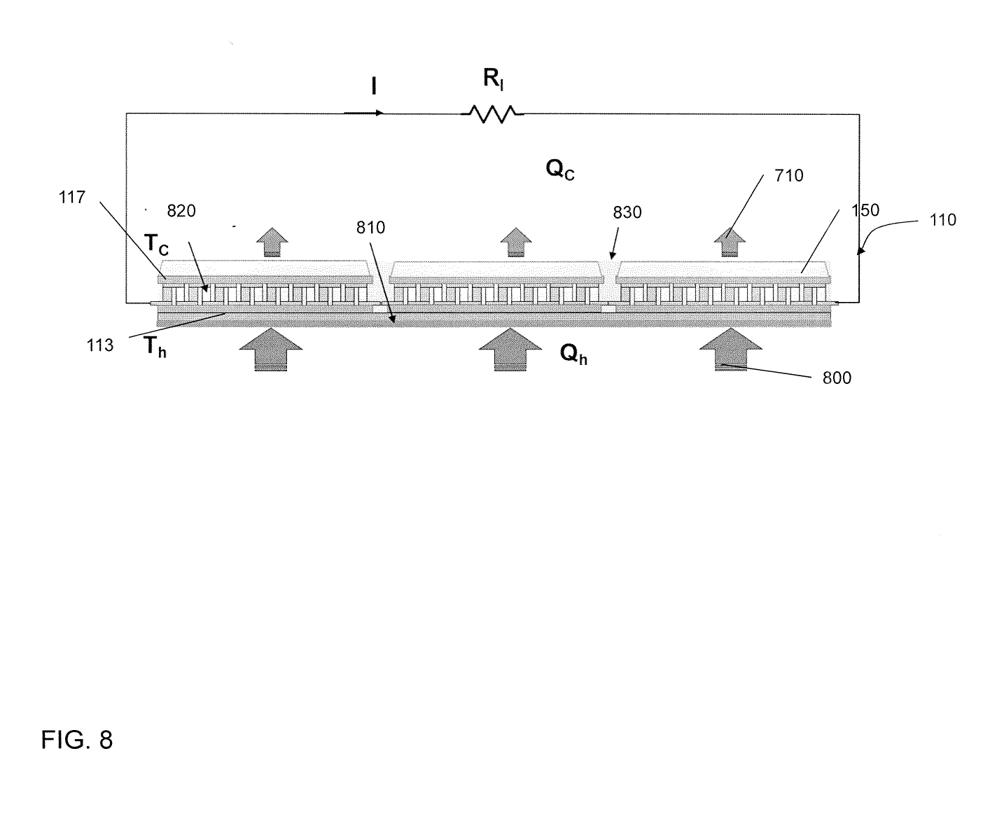

FIG. 8 shows an exemplary thermoelectric generator 110 of FIG. 7 with light energy 800 directed towards the hot side 113. A light absorbing layer 810 may disposed on the hot side 113 of the thermoelectric generator 110 between the light energy 800 and the hot side 113. The light absorbing layer 810 includes a light absorbing material selected to convert light energy into heat energy over a range of wavelengths. In some embodiments, the light absorbing substance may be selected that provides a high degree of absorption along the solar spectral range and low emittance in the wavelengths corresponding to the infra-red range. The light absorbing layer 810 may be configured to remain operable after exposure to heat source 130 and to have a minimal or no effect on the heat flow from heat source 130 to the hot side 113. The range of wavelengths may include, but are not limited to, the visible and ultraviolet light spectra. Also shown is the matrix of n- and p-material elements 820 that perform the thermoelectric conversion in the thermoelectric generator 110. The matrix 820 may be separated into sections by one or more insulator layers 830. The insulator layers 830 may include an aerogel insulating material.

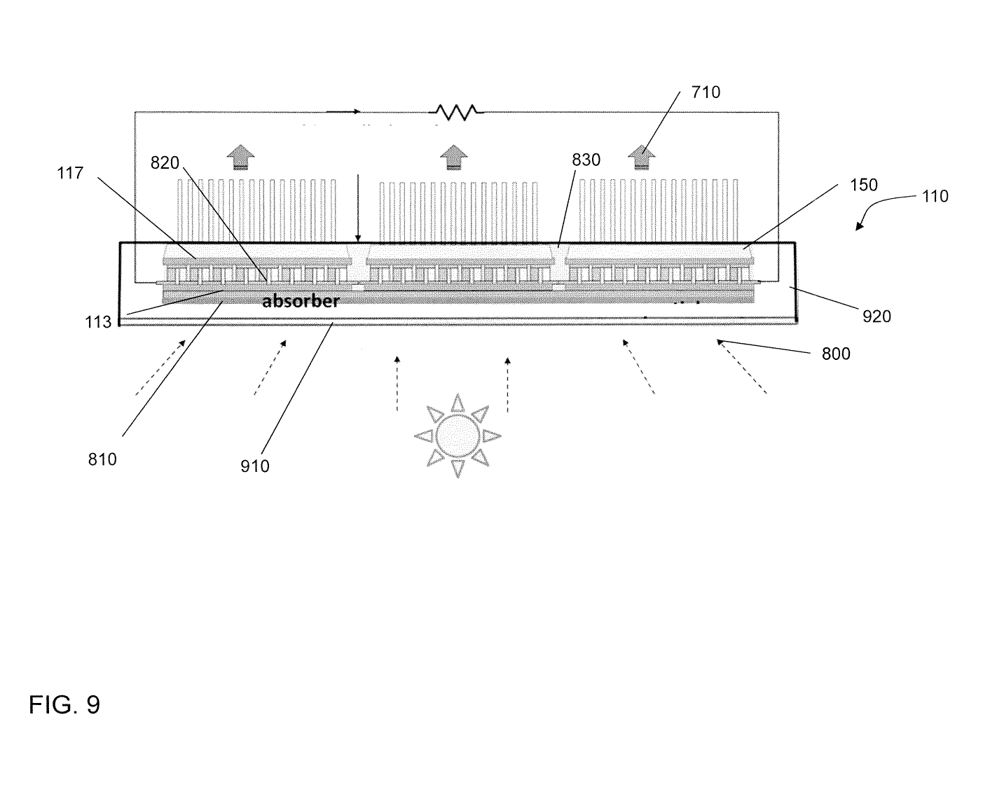

FIG. 9 shows an exemplary thermoelectric generator 110 of FIG. 8 with a light director such as lens 910 disposed between the light absorbing layer 810 and the light energy 800. The light director may include one or more lens and/or one or more reflectors configured to direct the light energy 800 to the light absorbing layer 810. The light energy 800 may come from an artificial or a natural source (e. g. sunlight). The lens 910 may be transparent and, in some embodiments, the lens 910 may be made of glass or plastic. The lens 910 may be configured to focus the light energy 800 on the light absorbing layer 810. In some embodiments, the lens 910 may not change the direction of the light energy 800. In some embodiments, the lens 910 may include a Fresnel lens. The lens 910 may be part of an atmospheric housing 920. The atmospheric housing 920 may be configured to maintain a partial vacuum around the light absorbing layer 810. In some embodiments, the atmospheric housing 920 may be configured to receive the lens 910. In some embodiments, the lens 910 may be configured to aid in maintaining the partial vacuum. As shown, the atmospheric housing 920 encompasses the light absorbing layer 810, the thermoelectric generator 110, and part of the heat sink 150. This configuration is exemplary and illustrative only, as other configurations may be used that preserve at least a partial vacuum between the lens 910 and the light absorbing layer 810, such as a configuration where the heat sink 150 is disposed on the exterior of the atmospheric housing 920. In some embodiments, the atmospheric housing 920 is optional. In some embodiments, the atmospheric housing 920 is comprised of a high heat conductive material(s) so as to no inhibit the heat flow to and from the thermoelectric generator 110. In some embodiments, a flat or concave reflector (not shown) may be used to direct light energy into the lens 910.

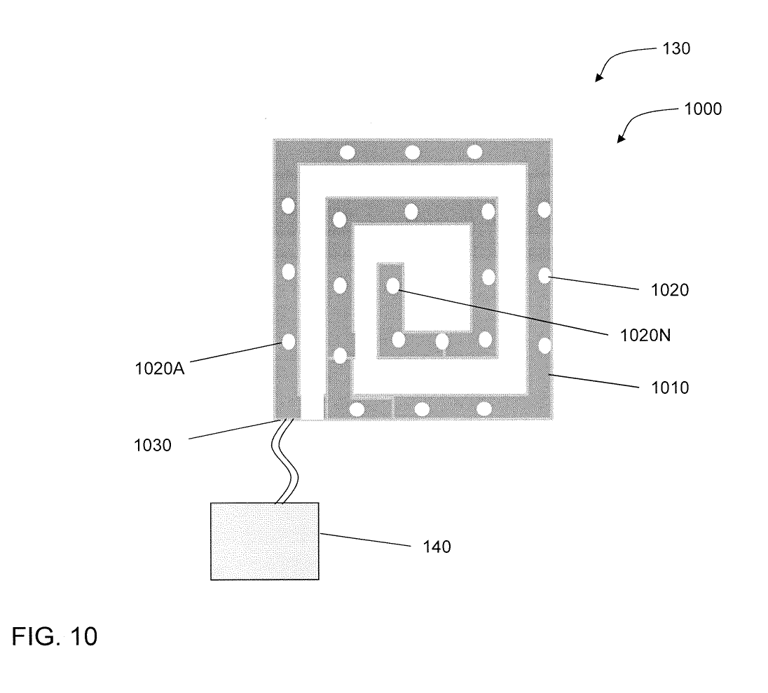

FIG. 10 shows another exemplary heat source 130 according to one embodiment of the present disclosure. The heat source 130 may include a combustor 1000. Combustor 1000 may include a combustor manifold 1010. The combustor manifold 1010 may be metal or ceramic. The combustor manifold 1010 may include nozzles 1020 configured to allow fuel from the fuel source 140 to mix with oxygen for efficient combustion. Equal area nozzles may result in incomplete combustion, thus, the area of the nozzles 1020 may be varied within the combustor manifold 1020 to reduce combustion inefficiency. In some embodiments, the area of the nozzles 1020 may be selected based on a model. The model may include using a mathematical relationship between the nozzle position along the combustor manifold 1010 and the nozzle area, such as a geometrical relationship. A first nozzle 1020A is located nearest to the fuel input 1030 for the combustion manifold 1010, and a last nozzle 1020N is located furthest from the fuel input 1030 of the combustion manifold 1010.

For example, assuming laminar flow of fuel in the combustion manifold 1010, the pressure drop (ΔP) in a fluid flowing through the combustion manifold 1010 with length L and radius r is given by the Hagen-Poiseuille equation:

$$Δ P = \frac{8 μ LQ}{π {r}^{4}} \qquad ( 1 )$$

where Q is the volumetric flow rate and μ is the dynamic viscosity of the fluid. If the total pressure at the fuel entry point 1030 of the combustion manifold 1010 is Pₒ, then pressure at the pressure at the n^{th} nozzle 1020N (Pₙ) may be determined by the following relation:

Pₙ=Pₒ−(n−1)ΔP (2)

where ΔP is the pressure drop in the tube between two adjacent nozzles is a constant drop determined by equation (1).

The volumetric flow out of the n^{th} nozzle 1040N may be determined by the following relation:

$${Q}_{orifice} = {CA}_{n} \sqrt{\frac{2 ( {P}_{n} - {P}_{atm} )}{ρ}} \qquad ( 3 )$$

where C is the orifice flow coefficient, μ is the fluid density, Pₐₜₘ is atmospheric pressure, and Aₙ is the cross sectional area of the nozzle orifice. Squaring both sides of equation (3) may result in:

$${P}_{n} - {P}_{atm} = \frac{{Q}_{orifice}^{2} ρ}{2 C {A}_{n}^{2}} \qquad ( 4 )$$

For a constant volumetric flow rate through the nozzle, equation (4) can be re-written as:

Aₙ²(Pₙ−Pₐₜₘ₎)=K (5)

where

$$K = \frac{{Q}_{orifice}^{2} ρ}{2 C}$$

is a constant.

Substituting equation (2) in equation (5):

Aₐ²[(Pₒ−Pₐₜₘ)−(n−1)ΔP]=K

Aₐ²[(Pₒ−Pₐₜₘ+ΔP)−nΔP]=K (6)

which may be expressed as:

$${A}_{n} = \frac{K}{\sqrt{[ ( {P}_{o} - {P}_{atm} + Δ P ) - n Δ P ]}} \qquad ( 7 )$$

Hence the nozzle area (Aₙ) increases down with distance from the fuel entry 1030 along the combustor manifold 1010 (i.e. the denominator of equation (7) reduces, as n increases).

In practice, the relations given by the equations (1) and (3) are complex and may vary due to highly turbulent flow (high Reynolds number) in the fuel. Thus, the nozzle areas maybe in a geometric relation such as:

Aₙ=A₁βⁿ⁻¹ (8)

where n is the nozzle index, A₁ is the area of the nozzle closest to the fuel input 1030, and the geometric ratio β is determined to provide uniform volume flow rate through the nozzles. While the nozzle area model equations are shown with a mathematical relationship that is geometrical, this is exemplary and illustrative only, as other mathematical relationships may be used to maintain a consistent fuel flow from the nozzles along the combustor manifold, including, but not limited to, an exponential progression.

The combustor manifold 1010 may include any number of the nozzles 1020. Here, the combustor manifold 1010 is shown in a square spiral pattern, however, this pattern is exemplary and illustrative, as the combustor manifold 1010 may have other patterns, such a ring, circular spiral, etc. The nozzles 1020 may vary in size from tens of microns in diameter to about one millimeter in diameter, with the smallest diameter nozzle 1020A being disposed closest to the fuel input 1030. In some embodiments, the combustor manifold 1010 may also transport fuel from the fuel source 140 in a liquid phase by capillary action using metal or ceramic wicks or sintered metal surfaces. In some embodiments, the fuel may be injected into the combustor manifold 1010 by one or more of: fuel pressure and air injection.

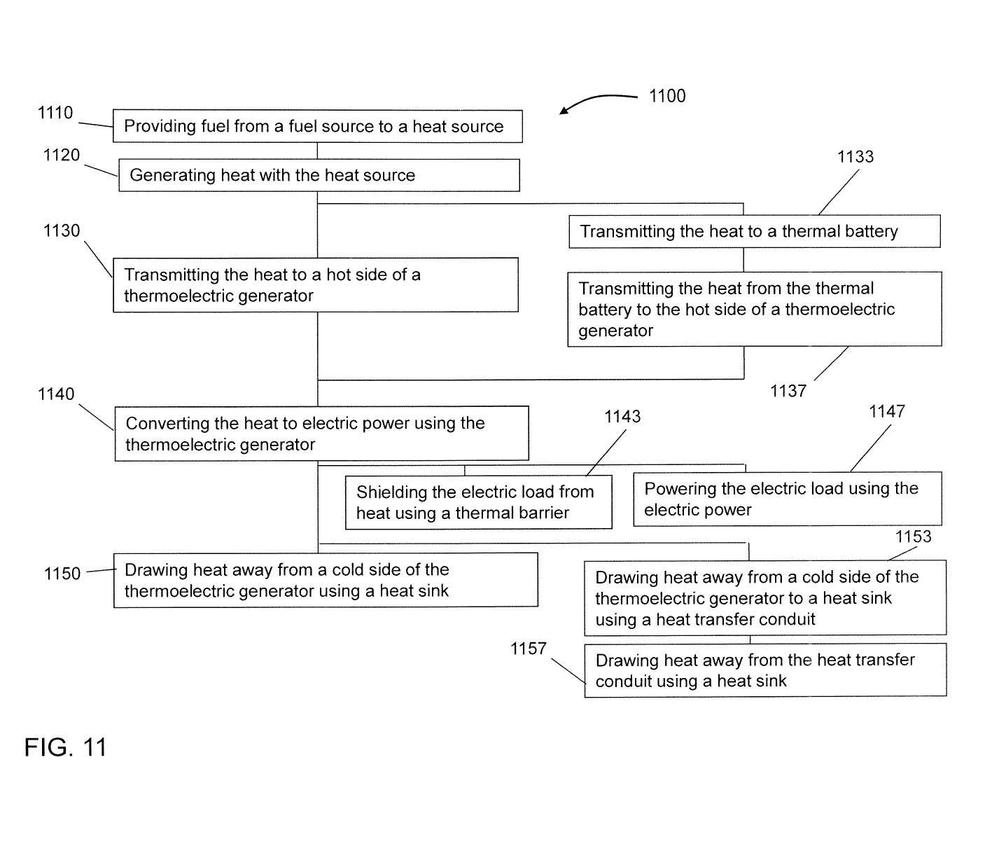

FIG. 11 shows an exemplary method 1100 according to one embodiment of the present disclosure. In step 1110, fuel from the fuel source 140 may be provided to the heat source 130. In some embodiments, the fuel may be a hydrocarbon. Suitable hydrocarbon fuels may include, but are not limited to, kerosene, liquefied petroleum gas (LPG), liquefied natural gas (LNG), raw natural gas (raw or refined), jet fuels, alcohols, and butane. In some embodiments, the fuel source 140 may include at least one of: i) a fuel tank and ii) a fuel line. In step 1120, heat energy may be generated using the heat source 130. The heat source 130 may include a combustor. In some embodiments, a non-combustive heat source may be used. In some embodiments, where a non-combustive heat source is used, step 1110 may be optional. In step 1130, the heat from the heat source 130 may be transmitted to the hot side 113 of the thermoelectric generator 110. The heat from fuel combustion may be transmitted to the hot side 113 via convection and/or radiative heat transfer. In an alternative step 1133, the heat from the heat source 120 may be transmitted to an optional thermal battery 120, and then, in step 1137, the heat may be transmitted from the thermal battery 120 to the hot side 113 of the thermoelectric generator 110. The use of thermal battery 120 may delay or regulate the amount of heat transmitted to the thermoelectric generator 110.

In step 1140, the heat may be converted into electric power using the thermoelectric generator 110. In step 1143, an optional thermal barrier 510 may shield the electric load 160, 170 from heat on the heat sink 150 and/or the cold side 117 of the thermoelectric generator 110. In step 1147, the electric load 160, 170 may receive electric power from the thermoelectric generator 110. In some embodiments, the electric power from the thermoelectric generator 110 may be stored and regulated by a conversion device 180 disposed between the thermoelectric generator 110 and the electric load 160, 170. In step 1150, the heat from the cold side 117 may be drawn away by a heat sink 150. In the alternative, in step 1153, the heat may be drawn away by a thermal diode 410, which, in step 1157, is further drawn away and dissipated to ambient by the heat sink 150. In some embodiments, both step 1150 and steps 1153 and 1157 may be performed. In some embodiments, step 1143, step 1147, step 1150 and/or steps 1153 and 1157 may take place in parallel.

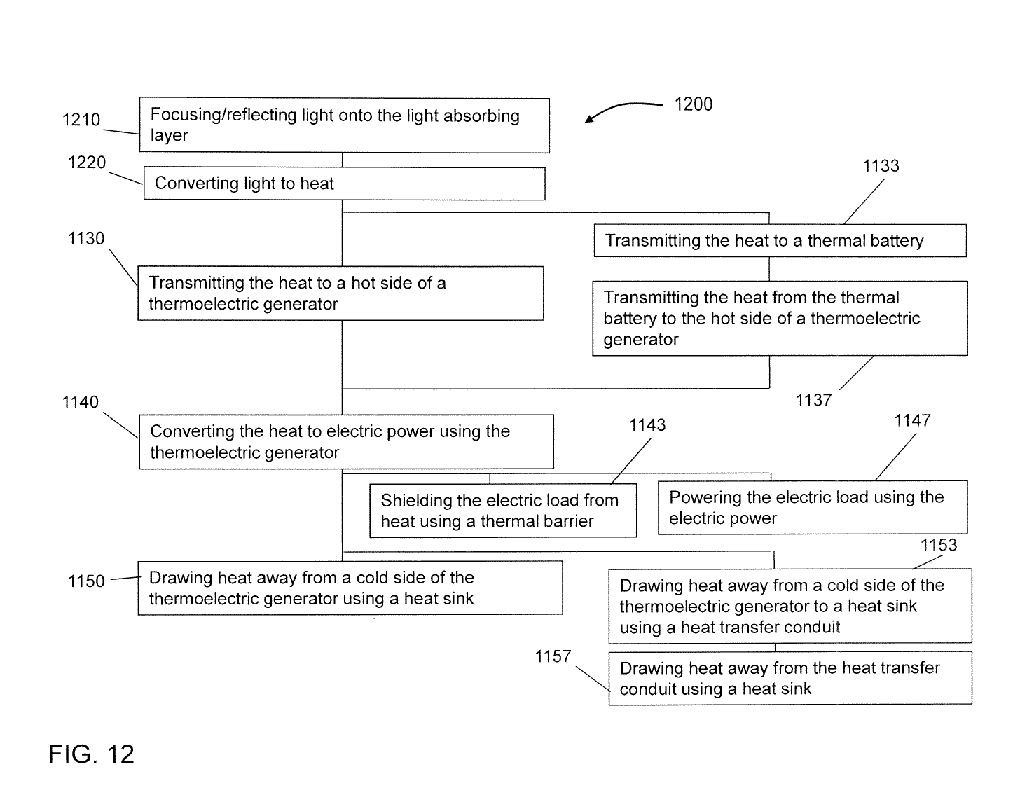

FIG. 12 shows another exemplary method 1200 according to one embodiment of the present disclosure. The method 1200 may include steps from method 1100, and also includes steps for heating the thermoelectric generator using light energy. In step 1210, light 800 is focused and/or reflected onto the light absorbing layer 810. In some embodiments, the lens 910 maybe used in the focusing. In some embodiments, the atmospheric housing 920 may maintain a partial vacuum around the light absorbing layer 810. In step 1220, heat energy may be generated from the light energy 800 absorbed by the light absorbing layer 810.

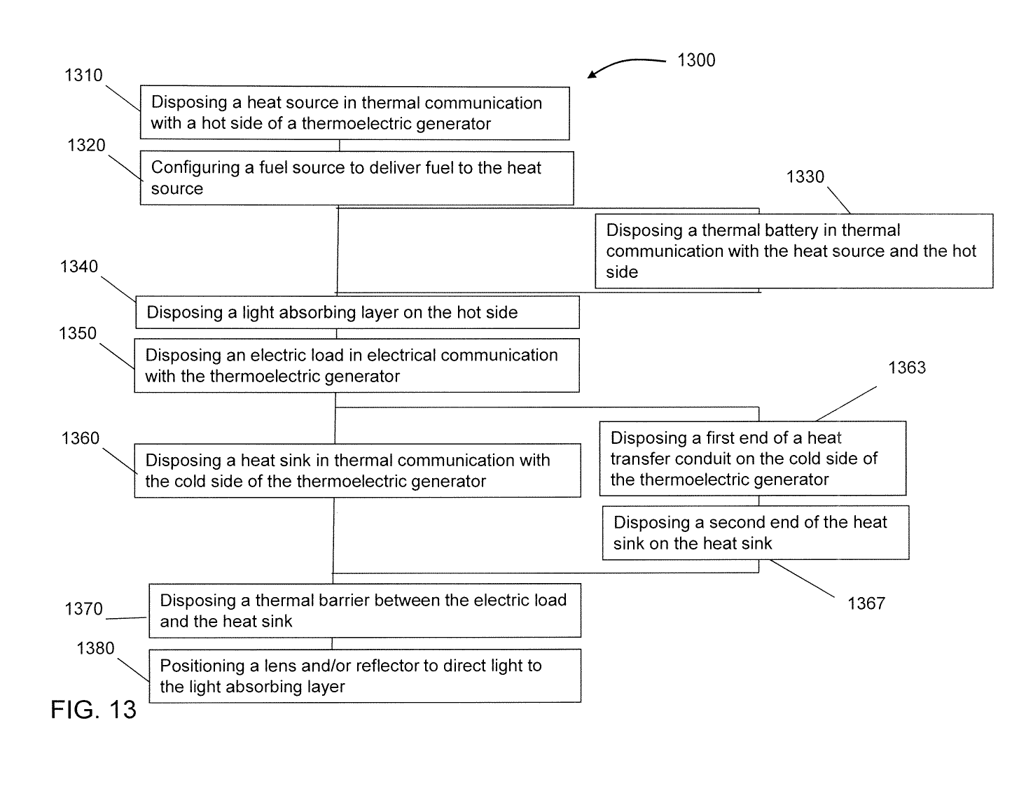

FIG. 13 shows another exemplary method 1300 according to one embodiment of the present disclosure. The method 1300 includes steps for manufacturing an apparatus that may be used with one or both of method 1100 and 1200. In step 1310, the heat source 130 may be disposed in thermal communication with the hot side 113 of the thermoelectric generator 110. The heat source 130 may be combustive or non-combustive. In step 1320, the fuel source 140 may be configured to deliver fuel to the heat source 130. In some embodiments, step 1320 may be optional. In step 1330, the thermal battery 120 may be disposed in thermal communication with both the heat source 130 and the hot side 117. In some embodiments, the thermal battery 120 may be physically between the heat source 130 and the hot side 117. In step 1340, the light absorbing layer 810 may be disposed on the hot side 117 In step 1350, the electric load 160, 170 may be disposed in electrical communication with the thermoelectric generator 110. In step 1360, the heat sink 150 may be disposed in thermal communication with the cold side 113. Alternatively, in step 1363, the first end of the thermal diode 410 may be disposed on the cold side 113 and, in step 1367, the second end of the thermal diode 410 may be disposed on the heat sink 150. In step 1370, the thermal barrier 510 may be disposed between the electric load 160, 170 and the heat sink 150 and/or the thermoelectric generator 110. In step 1380, a lens and/or reflector may be positioned to direct light to the light absorbing layer 810. In some embodiments, any of steps 1330, 1340, 1370, and 1380 may be optional. In some embodiments, one, none, or both of i) step 1360 and ii) steps 1363 and 1367 may be performed.

While the disclosure has been described with reference to exemplary embodiments, it will be understood that various changes may be made and equivalents may be substituted for elements thereof without departing from the scope of the disclosure. In addition, many modifications will be appreciated to adapt a particular instrument, situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

1-38. (canceled)

39. An apparatus for generating electric power, the apparatus comprising:
a thermoelectric generator, the thermoelectric generator having a hot side and a cold side; and
a non-combustive heat source in thermal communication with the hot side.

40. The apparatus of claim 39, wherein the non-combustive heat source is configured to transmit heat from at least one of: i) an exothermic chemical reaction, ii) a thermophysical phase change, iii) an optothermal phase change, and iv) radioactive decay.

41. The apparatus of claim 39, further comprising:
a light absorbing layer disposed on the hot side of the thermoelectric generator and configured to convert light to heat; and
a light director configured to transmit light to the light absorbing layer.

42. The apparatus of claim 41, wherein the light source comprises at least one of i) a reflector and ii) a lens.

43. The apparatus of claim 39, further comprising:
a thermal battery, wherein the thermal battery is in thermal communication with the non-combustive heat source and the hot side of the thermoelectric generator.

44. The apparatus of claim 43, wherein the thermal battery is disposed between the non-combustive heat source and the hot side of the thermoelectric generator.

45. The apparatus of claim 43, wherein the thermal battery comprises:
an insulated housing; and
an energy storage material disposed within the insulated housing.

46. The apparatus of claim 45, wherein the insulated housing comprises an aerogel insulating material.

47. The apparatus of claim 45, wherein the energy storage material comprises at least one of a phase change material and a reversible exothermic hydration material.

48. The apparatus of claim 47, wherein the phase change material comprises at least one of: i a molten salt, ii) a molten metal, iii) a molten metal alloy, iv) a molten metallic compound, and v) an ionic liquid.

49. The apparatus of claim 47, wherein the reversible exothermic hydration material comprises an alkali metal oxide.

50. The apparatus of claim 39, further comprising:
an electric load in electrical communication with the thermoelectric generator

51. The apparatus of claim 50, wherein the electric load comprises at least one of: i) an electric light and ii) an electric battery-operated device.

52. The apparatus of claim 39, wherein the fuel source comprises a hydrocarbon fuel.

53. The apparatus of claim 39, wherein the thermoelectric generator is a thin-film thermoelectric generator.

54. The apparatus of claim 39, further comprising:
a heat sink disposed on the cold side of the thermoelectric generator.

55. The apparatus of claim 39, further comprising:
a thermal diode disposed on the cold side of the thermoelectric generator; and
a heat sink disposed on the thermal diode.

56. The apparatus of claim 55, wherein the thermal diode includes at least one of: i) a heat pipe and ii) a thermosyphon.

57. The apparatus of claim 55, further comprising:
an electric load in electrical communication with the thermoelectric generator; and
a thermal harrier disposed between the electric load and the heat sink.

58. The apparatus of claim 57, wherein the thermal barrier comprises at least one of: i) a thermal reflector and ii) an insulation layer.

59. The apparatus of claim 39, wherein the fuel source comprises at least one of: i) a fuel tank and ii) a fuel line.

60. A method of generating electric power, the method comprising:
generating electric power using an apparatus, the apparatus comprising:
a thermoelectric generator, the thermoelectric generator having a hot side and a cold side;
a non-combustive heat source in thermal communication with the hot side of the thermoelectric generator.

61. The method of claim 60, wherein the step of generating electric power comprises:
generating heat with the non-combustive heat source;
transmitting the heat to the hot side of the thermoelectric generator; and
converting the heat to electricity using the thermoelectric generator.

62. The method of claim 61, wherein the step of generating heat comprises at least one of:
using heat from an exothermic chemical reaction;
using heat from a thermophysical phase change;
using heat from an optothermal phase change; and
using heat from radioactive decay.

63. The method claim 61, wherein the step of transmitting the heat comprises:
storing the heat from the non-combustive heat source in a thermal battery; and
conducting, the heat from the thermal battery to the hot side of the thermoelectric generator.

64. The method of claim 60, further comprising:
powering an electric load with the generated electricity.

65. The method of claim 64, wherein the electric load comprises at least one of: i) an electric light and ii) an electric battery.

66. The method of claim 60, further comprising:
removing heat from the cold side of the thermoelectric generator.

67. The method of claim 66, wherein the step of removing heat comprises:
drawing heat away from the cold side using a heat sink in thermal communication with the cold side.

68. The method of claim 67, wherein a thermal diode is disposed between the heat sink and the cold side.

69. The method of claim 67, further comprising:
shielding an electric load from heat at the heat sink, wherein the electric load is in electrical comma with the thermoelectric generator.

70. The method of claim 60, wherein the apparatus further comprises:
a light absorbing layer disposed on the hot side and configured to convert light to heat; and
the method further comprises:
directing light energy to the Light absorbing layer.

71.-91. (canceled)
